(19) United States
(12) Patent Application Publication
(10) Pub. No.: US 2026/0033222 A1
(43) Pub. Date: Jan. 29, 2026

(54) DISPLAY APPARATUS HAVING AN EMISSION AREA AND A TRANSMISSION AREA

(71) Applicant: LG Display Co., Ltd., Seoul (KR)

(72) Inventor: Do Hyung KIM, Paju-si (KR)

(73) Assignee: LG Display Co., Ltd., Seoul (KR)

(21) Appl. No.: 19/195,556

(22) Filed: Apr. 30, 2025

(30) Foreign Application Priority Data
Jul. 26, 2024 (KR) 10-2024-0099359

(51) Int. Cl. H10K 59/80

(52) U.S. Cl. CPC H10K 59/879; H10K 59/873

(57) ABSTRACT

A display apparatus including a transmission area is provided. The display apparatus can include a light-emitting device on an emission area. The transmission area can be disposed outside the emission area. The light-emitting device can be disposed between a first optical lens and a second optical lens. The first optical lens and the second optical lens can overlap the transmission area. A cross-section of the second optical lens can be symmetrical to a cross-section of the first optical lens with respect to the light-emitting device. The second optical lens does not overlap the first optical lens. Thus, in the display apparatus, the amount of external light passing through the transmission area can be increased without the decrease in a viewing angle of real image by the external light.

### CROSS-REFERENCE TO RELATED APPLICATIONS

This application claims the benefit of Korean Patent Application No. 10-2024-0099359, filed on Jul. 26, 2024, which is hereby incorporated by reference as if fully set forth herein.

### BACKGROUND

### Technical Field

The present disclosure relates to a display apparatus in which each of pixel areas includes an emission area and a transmission area.

### Description of the Related Art

Generally, a display apparatus provides an image to a user. For example, the display apparatus can include at least one light-emitting device. The light-emitting device can emit light displaying a specific color. For example, the light-emitting device can include a light-emitting unit disposed between a first electrode and a second electrode.

If light is not emitted from the light-emitting device, the display apparatus can be recognized as a transparent glass by the user. For example, the display apparatus can include an emission area in which the light-emitting device is disposed and a transmission area disposed outside the emission area. Thus, in the display apparatus, the real image by external light passing through the transmission area can be provided to the user.

### BRIEF SUMMARY

Accordingly, the present disclosure is directed to a display apparatus that substantially obviates one or more problems due to limitations and disadvantages of the related art.

Various embodiments of a transparent display apparatus feature a novel dual-lens optical structure designed to enhance the clarity and brightness of real-world images seen through the display. The display includes light-emitting devices arranged between two distinct types of convex optical lenses-one on the top surface (first optical lens) and one on the bottom surface (second optical lens) of the device substrate. These lenses are positioned over separate transmission areas and are symmetrically shaped relative to the substrate, ensuring that external light is efficiently transmitted through the display from either direction. Importantly, the lenses are spatially separated from the emission areas and do not overlap with each other or the emitted light path.

This configuration significantly improves the amount of external light passing through the transmission areas without compromising the viewing angle, the clarity of real images, or the size of the emission areas. As a result, the display offers better transparency when inactive and improved image quality, all while enabling low-power operation. The structure also allows for manufacturing flexibility, as the lenses can be formed using various materials and techniques, including etching directly into the substrate or integrating within passivation layers.

Various embodiments of the present disclosure provide a display apparatus capable of improving the clarity of the real image by the external light passing through a transmission area.

Various embodiments of the present disclosure provide a display apparatus capable of increasing the amount of the external light passing through the transmission area, without the decrease in a viewing angle of the real image by the external light.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. The device substrate includes an emission area, a first transmission area and a second transmission area. A light-emitting device and an encapsulation structure are disposed on a first surface of the device substrate. The light-emitting device overlaps the emission area. The encapsulation structure covers the light-emitting device. A first optical lens is disposed on the encapsulation structure. The first optical lens overlaps the first transmission area. A second optical lens is disposed on a second surface of the device substrate. The second optical lens overlaps the second transmission area. A cross-section of the second optical lens has a shape symmetrical to a cross-section of the first optical lens with respect to the device substrate.

The cross-section of the first optical lens can have a semicircular shape with respect to the device substrate.

The first optical lens can be disposed outside the second transmission area. The second optical lens can be disposed outside the first transmission area.

A non-emission area can be disposed between the emission area, the first transmission area and the second transmission area. An edge of the first optical lens and an edge of the second optical lens can overlap the non-emission area.

A refractive index of the second optical lens can be different from a refractive index of the first optical lens.

A lens passivation layer can be disposed on the encapsulation structure. The first optical lens can be covered by the lens passivation layer. A refractive index of the lens passivation layer can be smaller than the refractive index of the first optical lens.

A color filter can be disposed on the encapsulation structure. The color filter can overlap the emission area. The first transmission area and the second transmission area can be disposed outside the color filter.

An encapsulating substrate can be disposed between the encapsulation structure and the first optical lens. The color filter can be disposed between the encapsulation structure and the encapsulating substrate.

In another embodiment, there is provided a display apparatus comprising first optical lenses and second optical lenses. The first optical lenses and the second optical lenses are disposed side by side in a first direction. The second optical lenses are spaced apart from the first optical lenses in a second direction. The second direction is a direction perpendicular to the first direction. Light-emitting devices are disposed between the first optical lenses and the second optical lenses in the second direction. Each of the first optical lenses and each of the second optical lenses have a cross-section having a convex shape in a direction opposite to the light-emitting devices. The second optical lenses are disposed alternately with the first optical lenses.

The light-emitting devices can be disposed between the first optical lenses and the second optical lenses in the first direction.

The light-emitting device and the first optical lenses can be supported by a device substrate. The second optical lenses can include a same material as the device substrate.

A buffer insulating layer can be disposed between the device substrate and the light-emitting devices. A surface of the device substrate and a surface of each second optical lens toward the light-emitting devices can be in contact with the buffer insulating layer.

The first optical lenses can include a same material as the second optical lenses.

An encapsulating substrate can be disposed on the light-emitting devices. The encapsulating substrate can be disposed on a same layer as the first optical lenses.

The surface of each second optical lens having a convex shape can have a same curvature as the surface of each first optical lens having a convex shape.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K region in FIG. 1;

FIG. 4 is a view taken along I-I′ of FIG. 3;

FIG. 5 is a view taken along II-II′ of FIG. 3; and

FIGS. 6 to 15 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “in contact,” “coupled” should be interpreted in the same manner.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

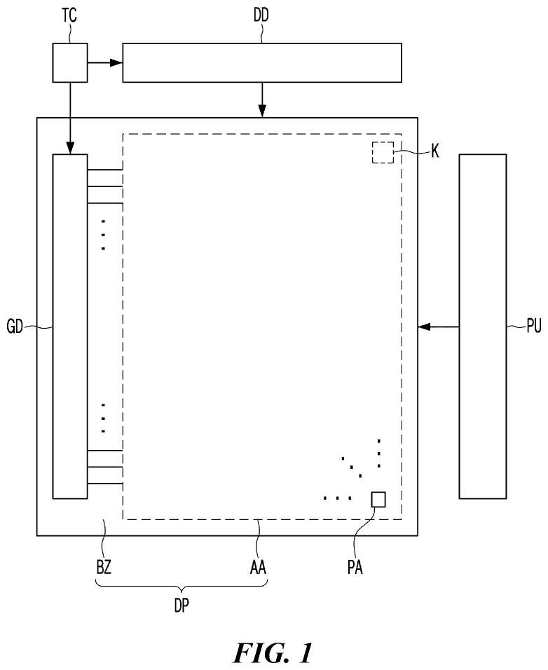

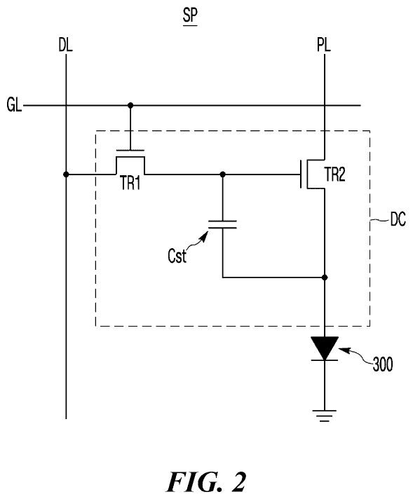

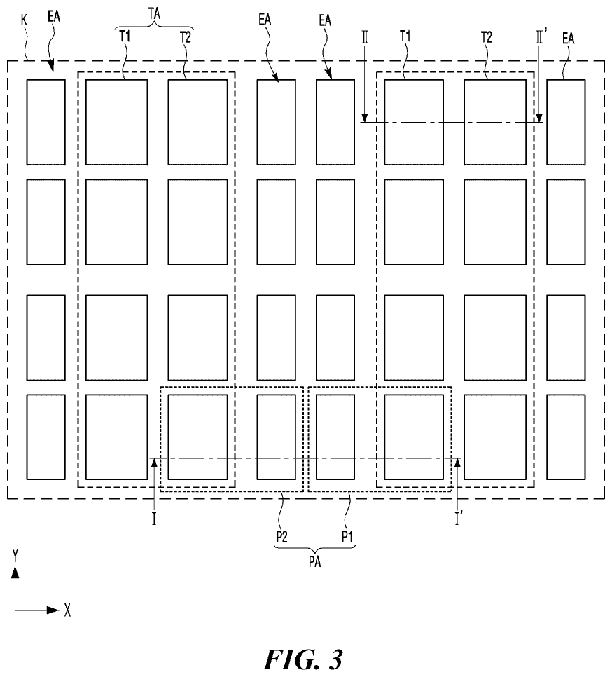

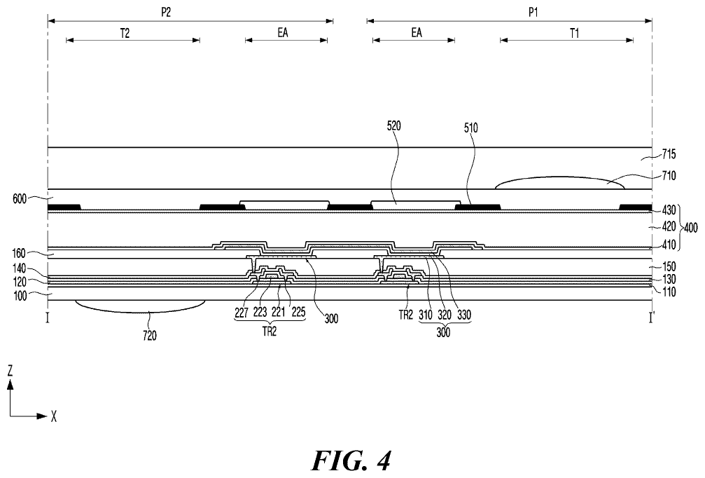

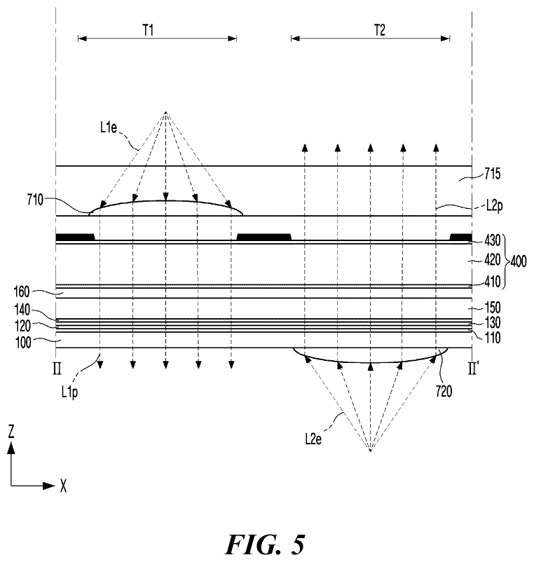

FIG. 1 is a view schematically showing a display apparatus according to an embodiment of the present disclosure. FIG. 2 is a view showing a circuit of a pixel area in the display apparatus according to the embodiment of the present disclosure. FIG. 3 is an enlarged view of K region in FIG. 1. FIG. 4 is a view taken along I-I′ of FIG. 3. FIG. 5 is a view taken along II-II′ of FIG. 3.

Referring to FIGS. 1 to 5, the display apparatus according to the embodiment of the present disclosure can include a display panel DP. The display panel DP can generate an image provided to a user. For example, a plurality of pixel areas PA can be disposed within the display panel DP. Various signals can be transmitted to each pixel area PA through signal wirings GL, DL and PL. For example, the signal wirings GL, DL and PL can include gate lines GL applying a gate signal, data lines DL applying a data signal and power voltage supply lings PL supplying a power voltage.

The gate lines GL can be electrically connected to a gate driver GD. The data lines DL can be electrically connected to a data driver DD. The power voltage supply lines PL can be electrically connected to a power unit PU. The gate driver GD and the data driver DD can be controlled by a timing controller TC. For example, the gate driver GD can receive clock signals, reset signals and a start signal from the timing controller TC, and the data driver DD can receive a digital video data and a source timing signal from the timing controller TC.

The display panel DP can include an active area AA and a bezel area BZ. The plurality of pixel areas PA can be disposed within the active area AA. The bezel area BZ can be disposed outside the active area AA. For example, the active area AA can be surrounded by the bezel area BZ. The gate driver GD, the data driver DD, the power unit PU and the timing controller TC can be disposed outside the active area AA. For example, each of the signal wirings GL, DL and PL can include a region disposed on the bezel area BZ. At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color. For example, a light-emitting device 300 can be disposed in each pixel area PA. The light-emitting device 300 of each pixel area PA can emit light displaying a specific color. For example, the light-emitting device 300 of each pixel area PA can include a light-emitting unit 320 disposed between the first electrode 310 and the second electrode 330.

The first electrode 310 can include a conductive material. The first electrode 310 can include a material having high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the first electrode 310 and the second electrode 330. For example, the light-emitting unit 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material. The light-emitting unit 320 can further include at least one functional layer to smooth supply of holes and/or electrons. For example, the light-emitting unit 320 can further include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting unit 320 can be improved.

The second electrode 330 can include a conductive material. The second electrode 330 can include a different material from the first electrode 310. For example, the second electrode 330 can have a lower work-function than the first electrode 310. Thus, in the display apparatus according to the embodiment of the present disclosure, the first electrode 310 can function as anode electrode, and the second electrode 330 can function as cathode electrode. A transmittance of the second electrode 330 can be higher than a transmittance of the first electrode 310. For example, the second electrode 330 can be a transparent electrode made of a transparent conductive material, such as ITO and IZO. Therefore, in the display apparatus according to the embodiment of the present disclosure, the light generated by the light-emitting unit 320 of each pixel area PA can be emitted through the second electrode 330 of the corresponding pixel area PA.

A driving circuit DC for controlling the operation of the light-emitting device 300 can be disposed in each pixel area PA. For example, the light-emitting device 300 of each pixel area PA can be electrically connected to the driving circuit DC of the corresponding pixel area PA. The driving circuit DC of each pixel area PA can generate a driving current according to a signal applied through the signal wirings GL, DL and PL. For example, the driving circuit DC of each pixel area PA can be electrically connected to one of the gate lines GL, one of the data lines DL and one of the power voltage supply lines PL. The driving current generated by the driving circuit DC of each pixel area PA can be supplied to the light-emitting device 300 of the corresponding pixel area PA for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can have a same structure as the first thin film transistor TR1 of the corresponding pixel area PA. For example, the second thin film transistor TR2 of each pixel area PA can include a second semiconductor pattern 221, a second gate electrode 223, a second drain electrode 225 and a second source electrode 227. The second gate electrode 223 of each pixel area PA can be electrically connected to the first source electrode of the corresponding pixel area PA, and the second drain electrode 225 of each pixel area PA can be electrically connected to the corresponding power voltage supply line PL.

The second semiconductor pattern 221 can include a semiconductor material. For example, the second semiconductor pattern 221 can include a lower temperature poly-Si (LTPS) or an oxide semiconductor, such as IGZO. The second semiconductor pattern 221 can include a drain region, a channel region and a source region. The channel region can be disposed between the drain region and the source region. The drain region and the source region can have a smaller resistance than the channel region. For example, the drain region and the source region can include a conductive region of an oxide semiconductor. The channel region can be a region of an oxide semiconductor, which is not conductorized.

The first semiconductor pattern can include a same material as the second semiconductor pattern 221. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage applied to the second gate electrode 223. The source region of the second semiconductor pattern 221 can be electrically connected to the drain region of the second semiconductor pattern 221 according to a signal applied to the second gate electrode 223.

The first gate electrode can include a same material as the second gate electrode 223. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be electrically connected to the drain region of the second semiconductor pattern 221. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be insulated from the second gate electrode 223. For example, the second drain electrode 225 can be disposed on a different layer from the second gate electrode 223.

The first drain electrode can include a same material as the second drain electrode 225. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be electrically connected to the source region of the second semiconductor pattern 221. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be insulated from the second gate electrode 223. For example, the second source electrode 227 can be disposed on a different layer from the second gate electrode 223. The second source electrode 227 can be disposed on a same layer as the second drain electrode 225. The second source electrode 227 can be spaced apart from the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225.

The first source electrode can include a same material as the second source electrode 227. The second source electrode 227 can be disposed on a same layer as the first source electrode. For example, the first drain electrode, the first source electrode, the second drain electrode 225 and the second source electrode 227 can be formed simultaneously. Thus, in the display apparatus according to the embodiment of the present disclosure, a process of forming the first thin film transistor TR1 and the second thin film transistor TR2 of each pixel area PA can be simplified.

The storage capacitor Cst of each pixel area PA can maintain a voltage of a signal applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 233 of the corresponding pixel area PA, and a second capacitor electrode electrically connected to the second source electrode 227 of the corresponding pixel area PA. The storage capacitor Cst of each pixel area PA can be formed using a process of forming the first thin film transistor TR1 and the second thin film transistor TR2 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA. Thus, in the display apparatus according to the embodiment of the present disclosure, the process efficiency can be improved.

The driving circuit DC and the light-emitting device 300 of each pixel area PA can be supported by a device substrate 100. For example, the driving circuit DC and the light-emitting device 300 of each pixel area PA can be disposed on an upper surface of the device substrate 100. The device substrate 100 can include an insulating material. For example, the device substrate 100 can include glass or plastic. At least one insulating layers 110, 120, 130, 140, 150 and 160 for preventing unnecessary electrical connection can be disposed on the upper surface of the device substrate 100. For example, a buffer insulating layer 110, a gate insulating layer 120, an interlayer insulating layer 130, a device passivation layer 140, a planarization layer 150 and a bank insulating layer 160 can be disposed on the upper surface of the device substrate 100.

The buffer insulating layer 110 can be disposed close to the upper surface of the device substrate 100. The buffer insulating layer 110 can prevent pollution due to the device substrate 100 in a process of forming the driving circuit DC of each pixel area PA. For example, the upper surface of the device substrate 100 can be covered by the buffer insulating layer 110. The buffer insulating layer 110 can be in direct contact with the upper surface of the device substrate 100. The driving circuit DC of each pixel area PA can be disposed on the buffer insulating layer 110. For example, the first thin film transistor TR1, the second thin film transistor TR2 and the storage capacitor Cst of each pixel area PA can be spaced apart from the device substrate 100 by the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a stacked structure of an inorganic insulating layer made of silicon oxide (SiOx) and an inorganic insulating layer made of silicon nitride (SiNx).

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material.

The interlayer insulating layer 130 can be disposed on the gate insulating layer 120. The second drain electrode 225 and the second source electrode 227 of each pixel area PA may be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent the damage of the driving circuit DC in each pixel area PA due to external impact and moisture. For example, the first drain electrode, the first source electrode, the second drain electrode 225 and the second source electrode 227 of each pixel area PA can be covered by the device passivation layer 140. The device passivation layer 140 can include an insulating material. The device passivation layer 140 can include a material having relatively hard. For example, the device passivation layer 140 can include an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be flat. The upper surface of the planarization layer 150 can be parallel to the upper surface of the device substrate 100. The planarization layer 150 can include an insulating material. The planarization layer 150 can include a material having a relatively high fluidity. For example, the planarization layer 150 can include an organic insulating material.

The light-emitting device 300 of each pixel area PA may be disposed on the planarization layer 150. For example, the first electrode 310, the light-emitting unit 320 and the second electrode 330 of each pixel area PA can be sequentially stacked on the planarization layer 150. The light-emitting device 300 of each pixel area PA can be controlled independently from the light-emitting device 300 of adjacent pixel area PA. For example, the first electrode 310 of each pixel area PA can be insulated from the first electrode 310 of adjacent pixel area PA by the bank insulating layer 160. The bank insulating layer 160 can include an insulating material. For example, the bank insulating layer 160 can include an organic insulating material. The bank insulating layer 160 can be disposed on the planarization layer 150. The bank insulating layer 160 can include a different material from the planarization layer 150.

The bank insulating layer 160 can define an emission area EA in each pixel area PA. The first electrode 310 of each pixel area PA can be partially exposed by the bank insulating layer 160. For example, the bank insulating layer 160 can cover an edge of the first electrode 310 in each pixel area PA. The light-emitting unit 320 and the second electrode 330 of each pixel area PA can be stacked on a portion of the corresponding first electrode 310 exposed by the bank insulating layer 160. For example, the emission area EA of each pixel area PA can mean a region in which light is emitted from the light-emitting device 300 of the corresponding pixel area PA. The bank insulating layer 160 can overlap a non-emission area in which light is not generated from the light-emitting unit 320 of each pixel area PA. For example, the non-emission area can be disposed outside the emission area EA defined by the bank insulating layer 160 in each pixel area PA.

The first electrode 310 of each pixel area PA can be electrically connected to the driving circuit DC of the corresponding pixel area PA. A lower surface of the first electrode toward the device substrate 100 can be in direct contact with the upper surface of the planarization layer 150 in the emission area EA of each pixel area PA. For example, the first electrode 310 of each pixel area PA can be direct contact with the second source electrode 227 of the corresponding pixel area PA at the outside of the emission area EA defined in the corresponding pixel area PA. Thus, in the display apparatus according to the embodiment of the present disclosure, a portion of the first electrode 310 overlapping with the emission area EA of each pixel area PA can have a flat shape. Therefore, in the display apparatus according to the embodiment of the present disclosure, the luminance deviation due to the generation location of the light emitted from the light-emitting device 300 of each pixel area PA can be prevented.

The light emitted from the light-emitting device 300 of each pixel area PA can display a same color as the light emitted from the light-emitting device 300 of adjacent pixel area PA. For example, the light-emitting device 300 of each pixel area PA can emit white light. The light-emitting unit 320 of each pixel area PA can have a stacked structure same as the light-emitting unit 320 of adjacent pixel area PA. The light-emitting unit 320 of each pixel area PA can be formed by a same process as the light-emitting unit 320 of adjacent pixel area PA. For example, the light-emitting unit 320 of each pixel area PA can be formed simultaneously with the light-emitting unit 320 of adjacent pixel area PA. Thus, in the display apparatus according to the embodiment of the present disclosure, a process of forming the light-emitting unit 320 of each pixel area PA can be simplified. Therefore, in the display apparatus according to the embodiment of the present disclosure, the process efficiency can be improved.

A voltage of a signal applied to the second electrode 330 of each pixel area PA can be the same as a voltage of a signal applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode 330 of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA on the bank insulating layer 160. Thus, in the display apparatus according to the embodiment of the present disclosure, a process of forming the second electrode 330 of each pixel area PA can be simplified. And, in the display apparatus according to the embodiment of the present disclosure, the luminance of the light generated from the light-emitting unit 320 of each pixel area PA can be adjusted by the data signal applied to the driving circuit DC of the corresponding pixel area PA.

An encapsulation structure 400 can be disposed on the light-emitting device 300 of each pixel area PA. The encapsulation structure 400 can prevent the damage of the light-emitting device 300 in each pixel area PA due to the external impact and moisture. For example, the light-emitting device 300 of each pixel area PA can be covered by the encapsulation structure 400. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting devices 300 due to the external impact and moisture can be effectively prevented. A thickness difference due to the light-emitting device 300 of each pixel area PA can be removed by the second encapsulating layer 420 of the encapsulation structure 400. For example, an upper surface of the encapsulation structure 400 opposite to the device substrate 100 can be flat. The upper surface of the encapsulation structure 400 can be parallel to the upper surface of the device substrate 100.

A black matrix 510 can be disposed on the encapsulation structure 400. The black matrix 510 can be disposed outside the emission area EA defined in each pixel area PA. For example, the black matrix 510 can be disposed on the non-emission area. The black matrix 510 can overlap a portion of the bank insulating layer 160. The black matrix 510 can include a material capable of blocking light. For example, the black matrix 510 can include a black dye, such as carbon black. Thus, in the display apparatus according to the embodiment of the present disclosure, the light emitted from the light-emitting device 300 of each pixel area PA toward adjacent pixel area PA can be blocked by the black matrix 510. Therefore, in the display apparatus according to the embodiment of the present disclosure, the quality of the image recognized by the user can be improved.

The black matrix 510 can be in direct contact with the upper surface of the encapsulation structure 400. Color filters 520 can be disposed on a portion of the encapsulation structure 400 exposed by the black matrix 510. The color filters 520 can overlap the emission areas EA of the pixel areas PA. The color filter 520 of each pixel area PA can be disposed on a path of the light emitted from the light-emitting device 300 of the corresponding pixel area PA. For example, the light emitted from the light-emitting device 300 of each pixel area PA can be emitted outside passing through one of the color filters 520. The light passing through each color filter 520 can display a specific color. The color filter 520 of each pixel area PA can include a different material from the color filter 520 of adjacent pixel area PA. For example, the color filter 520 of each pixel area PA can be one of a red color filter displaying red color, a green color filter displaying green color and a blue color filter displaying blue color. Thus, in the display apparatus according to the embodiment of the present disclosure, the image provided to the user can include various colors.

A filter passivation layer 600 can be disposed on the black matrix 510 and the color filters 520. The filter passivation layer 600 can prevent the damage of the black matrix 510 and the damage of the color filters 520 due to the external impact and moisture. The filter passivation layer 600 can include an insulating material. The filter passivation layer 600 can include a transparent material. For example, the filter passivation layer 600 can include an inorganic insulating material and/or an organic insulating material. A thickness difference due to the black matrix 510 and the color filters 520 can be removed by the filter passivation layer 600. For example, an upper surface of the filter passivation layer 600 opposite to the device substrate 100 can be flat. The upper surface of the filter passivation layer 600 can be parallel to the upper surface of the encapsulation structure 400.

Each of the pixel areas PA can include a transmission area TA through which external light passes. For example, the transmission area TA of each pixel area PA can be disposed outside the emission area EA defined by the bank insulating layer 160 in the corresponding pixel area PA. The user can recognize a real image by the external light passing through the transmission area TA of each pixel area PA. For example, the display apparatus according to the embodiment of the present disclosure can be a transparent display apparatus recognized as a transparent glass by the user, when the light is not emitted from the light-emitting device 300 of each pixel area PA. The transmission area TA of each pixel area PA can have a different size from the emission area EA of the corresponding pixel area PA. For example, the transmission area TA of each pixel area PA can have a larger size than the emission area EA of the corresponding pixel area PA. Thus, in the display apparatus according to the embodiment of the present disclosure, the amount of the light passing through the transmission area TA of each pixel area PA can be increased. Therefore, in the display apparatus according to the embodiment of the present disclosure, the clarity of the real image by the external light passing through the transmission area TA of each pixel area PA can be improved.

The black matrix 510 and the color filters 520 cannot overlap the transmission area TA of each pixel area PA. For example, the emission area EA and the transmission area TA of each pixel area PA can be surrounded by the black matrix 510. Thus, in the display apparatus according to the embodiment of the present disclosure, the external light passing through the transmission area TA of each pixel area PA cannot be blocked by the black matrix 510. And, in the display apparatus according to the embodiment of the present disclosure, the peak wavelength of the external light passing through the transmission area TA of each pixel area PA cannot be shifted by the color filters 520. That is, in the display apparatus according to the embodiment of the present disclosure, the loss and the change of the external light passing through the transmission area Ta of each pixel area PA due to the black matrix 510 and the color filters 520 can be prevented. Therefore, in the display apparatus according to the embodiment of the present disclosure, the distortion of the real image recognized by the user through the transmission area TA of each pixel area PA can be prevented.

The pixel areas PA can be disposed side by side in a first direction X and a second direction Y perpendicular to the first direction X. The emission area EA and the transmission area TA of each pixel area PA can be disposed side by side in the first direction X. The emission area EA and the transmission area TA of each pixel area PA can be arrange in a same order as the emission area EA and the transmission area TA of the pixel area PA adjacent in the second direction Y. For example, in the display apparatus according to the embodiment of the present disclosure, the emission areas EA of the pixel areas PA can be disposed side by side in the second direction Y.

First optical lenses 710 can be disposed on the filter passivation layer 600. The first optical lenses 710 can be disposed on some of the pixel areas PA. For example, the pixel areas PA can include first pixel areas P1 and second pixel areas P2, which are repeated in the first direction X, each of the first optical lenses 710 can be disposed on a first transmission area T1 of one of the first pixel areas P1, and the second pixel areas P2 can be disposed outside the first optical lenses 710. The first optical lenses 710 can overlap the first transmission areas T1 of the first pixel areas P1, and each of the second pixel areas P2 can include a second transmission area T2 which does not overlap the first optical lenses 710. Each of the first optical lenses 710 can have a larger size than the first transmission area T1 of the corresponding first pixel area P1. For example, an edge of each first optical lens 710 can overlap the non-emission area. The first pixel areas P1 and the second pixel areas P2 can be arranged in the same order. For example, the first transmission area T1 of the first pixel areas P1 can be disposed side by side in the second direction Y, and the second transmission areas T2 of the second pixel areas P2 can be disposed side by side in the second direction Y.

The emission area EA and the first transmission area T1 of each first pixel area P1 can be disposed in a different order from the emission area EA and the second transmission area T2 of each second pixel area P2. The emission area EA of each second pixel area P2 can be disposed close to the emission area EA of each first pixel area P1. For example, in the display apparatus according to the embodiment of the present disclosure, the emission area EA of the first pixel area P1, the first transmission area T1 of the first pixel area P1, the second transmission area T2 of the second pixel area P2 and the emission area EA of the second pixel area P2 can be repeated in the first direction X. Thus, in the display apparatus according to the embodiment of the present disclosure, the process margin can be reduced in a process of forming the black matrix 510 and the color filters 520. Therefore, in the display apparatus according to the embodiment of the present disclosure, the efficiency in a process of forming the light-emitting device 300 of each pixel area PA can be improved. And, in the display apparatus according to the embodiment of the present disclosure, the clarity of the real image provided to the user through the transmission area TA of each pixel area PA can be improved.

A surface of each first optical lens 710 opposite to the device substrate 100 can have a convex shape toward a direction opposite to the device substrate 100. For example, a cross-section of each first optical lens 710 can have a semicircular shape with respect to the device substrate 100. The first optical lenses 710 can be covered by an upper lens passivation layer 715. For example, the surface of each first optical lens 710 having a convex shape can be in direct contact with the upper lens passivation layer 715. The upper lens passivation layer 715 can include an insulating material. For example, the upper lens passivation layer 715 can include an inorganic insulating material. A refractive index of the upper lens passivation layer 715 can be smaller than a refractive index of each first optical lens 710. Thus, in the display apparatus according to the embodiment of the present disclosure, the external light L1e incident on each first optical lens 710 through the upper lens passivation layer 715 can be refracted toward the center of the corresponding first optical lens 710 at a boundary between the corresponding first optical lens 710 and the upper lens passivation layer 715. The external light L1e incident on each first optical lens 710 through the upper lens passivation layer 715 can travel in various directions. For example, in the display apparatus according to the embodiment of the present disclosure, the external light L1p passing through each first optical lens 710 through the upper lens passivation layer 715 can travel parallel to each other by a difference in the refractive index of the upper lens passivation layer 715 and the corresponding first optical lens 710. Therefore, in the display apparatus according to the embodiment of the present disclosure, the amount of the external light L1p travelling toward the device substrate 100 passing through each first optical lens 710 can be increased.

Second optical lenses 720 can be disposed on a lower surface of the device substrate 100. The lower surface of the device substrate 100 can be opposite to the upper surface of the device substrate 100. For example, the device substrate 100 can be disposed between the light-emitting devices 300 and the second optical lenses 720. The light-emitting devices 300 can be disposed between the first optical lenses 710 and the second optical lenses 720 in a third direction Z perpendicular to the first direction X and the second direction Y. The second optical lenses 720 can be disposed some of the pixel areas PA. The second optical lenses 720 can be disposed alternately with the first optical lenses 710. For example, each of the second optical lenses 720 can overlap the second transmission area T2 of one of the second pixel areas P2, and the first pixel areas P1 can be disposed outside the second optical lenses 720. Each of the second optical lenses 720 can have a larger size than the second transmission area T2 of the corresponding second pixel area P2. For example, an edge of each second optical lens 720 can overlap the non-emission area. Each of the second optical lenses 720 can be spaced apart from the first optical lenses 710 in the first direction X and the second direction Y.

A surface of each second optical lens 720 opposite to the device substrate 100 can have a convex shape in a direction opposite to the device substrate 100. For example, a cross-section of each second optical lens 720 can have a semicircular shape with respect to the device substrate 100. The cross-section of each second optical lens 720 can have a shape symmetrical to the cross-section of each first optical lens 710 with respect to the device substrate 100. For example, the surface of each second optical lens 720 having a convex shape can have a same curvature as the surface of each first optical lens 710 having a convex shape. The second optical lenses 720 can include a different material from the first optical lenses 710. For example, a refractive index of each second optical lens 720 can be different from the refractive index of each first optical lens 710. The surface of each second optical lens 720 can be in direct contact with the air. Thus, in the display apparatus according to the embodiment of the present disclosure, the external light L2e incident on each second optical lens 720 on the lower surface of the device substrate 100 can be refracted toward the center of the corresponding second optical lens 720 at the surface of the corresponding second optical lens 720 having a convex shape. The external light L2e incident on each second optical lens 720 on the lower surface of the device substrate 100 can travel in various directions. For example, in the display apparatus according to the embodiment of the present disclosure, the external light L2p passing through each second optical lens 720 through the surface of the corresponding second optical lens 720 having a convex shape can travel parallel to each other by a different in the refractive index of the air and the corresponding second optical lens 720. Therefore, in the display apparatus according to the embodiment of the present disclosure, the amount of the external light L2p travelling toward the device substrate 100 passing through each second optical lens 720 can be increased.

The second optical lenses 720 cannot overlap the first optical lenses 710. For example, in the display apparatus according to the embodiment of the present disclosure, the external light L1p travelling toward the device substrate 100 passing through each first optical lens 710 cannot pass through the second optical lenses 720, and the external light L2p travelling toward the device substrate 100 passing through each second optical lens 720 cannot pass through the first optical lenses 710. Thus, in the display apparatus according to the embodiment of the present disclosure, the external light L1p passing through the device substrate 100 through each first optical lens 710 cannot be concentrated by the second optical lenses 720, and the external light L2p passing through the device substrate 100 through each second optical lens 720 cannot be concentrated by the first optical lenses 710. That is, in the display apparatus according to the embodiment of the present disclosure, a viewing angle of the external light L1p passing through the device substrate 100 through each first optical lens 710 and a viewing angle of the external light L2p passing through the device substrate 100 through each second optical lens 720 can be reduced. Therefore, in the display apparatus according to the embodiment of the present disclosure, the amount of the external light L1p and L2p provided to the user through the transmission area TA of each pixel area PA can be increased, without the decrease in the viewing angle of the external light L1p and L2p. And, in the display apparatus according to the embodiment of the present disclosure, the clarity of the real image recognized by the user by the external light L1p and L2p passing through the transmission area TA of each pixel area PA can be improved, regardless to the location of the user.

Accordingly, the display apparatus according to the embodiment of the present disclosure can comprise the light-emitting devices 300 disposed between the first optical lenses 710 and the second optical lenses 720 in the third direction Z, wherein the first optical lenses 710 and the second optical lenses 720 on the transmission areas TA of the pixel areas PA can be spaced apart from the emission areas EA of the pixel areas PA in which the light-emitting devices 300 are disposed, wherein the second optical lenses 720 can be disposed alternately with the first optical lenses 710, and wherein the cross-section of each second optical lens 720 can have a shape symmetrical to the cross-section of each first optical lens 710 with respect to the light-emitting devices 300. Thus, in the display apparatus according to the embodiment of the present disclosure, the amount of the external light L1p and L2p passing through the transmission area TA of each pixel area PA can be increased, without the decrease in the viewing angle of the external light L1p and L2p. Therefore, in the display apparatus according to the embodiment of the present disclosure, the clarity of the real image provided to the user through the transmission area TA of each pixel area PA can be improved.

And, in the display apparatus according to the embodiment of the present disclosure, the amount of the external light passing through the first transmission areas T1 of the device substrate 100 can be increased by the first optical lenses 710, and the amount of the external light passing through the second transmission areas T2 of the device substrate 100 can be increased by the second optical lenses 720. Thus, in the display apparatus according to the embodiment of the present disclosure, the real image located beyond the second optical lenses 720 and recognized by the user can have a same clarity as the real image located beyond the first optical lenses 710 and recognized by the user. Thus, in the display apparatus according to the embodiment of the present disclosure, a difference in the color sense and the luminance between the real image by the external light travelling from the lower surface of the device substrate 100 toward the upper surface of the device substrate 100 and the real image by the external light travelling from the upper surface of the device substrate 100 toward the lower surface of the device substrate 100 can be minimized. That is, in the display apparatus according to the embodiment of the present disclosure, the transmittance deviation according to a travelling direction of the external light passing through the device substrate 100 can be minimized.

Further, in the display apparatus according to the embodiment of the present disclosure, the amount of the external light passing through the device substrate 100 can be increased, without the reduction in a size of the emission areas EA. That is, in the display apparatus according to the embodiment of the present disclosure, a size of the emission area EA defined in each pixel area PA can be maximized, without the reduction in the amount of the external light. Thus, in the display apparatus according to the embodiment of the present disclosure, the low power driving can be possible, and the power consumption can be reduced.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to one of the gate lines GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 of each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

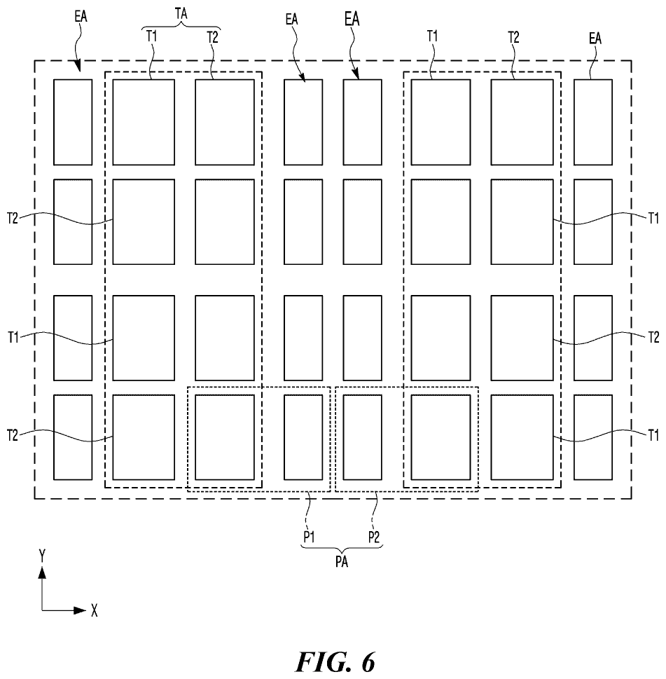

The display apparatus according to the embodiment of the present disclosure is described that the first transmission areas T1 and the second transmission areas T2 are disposed side by side in the second direction Y. However, in the display apparatus according to another embodiment of the present disclosure, the first transmission areas T1 and the second transmission areas T2 can be arranged in various ways. For example, in the display apparatus according to another embodiment of the present disclosure, the second transmission areas T2 can be arranged alternately with the first transmission areas T1 in the first direction X and the second direction Y, as shown in FIG. 6. The first pixel areas P1 and the second pixel areas P2 can be repeatedly disposed in the first direction X and the second direction Y. Thus, in the display apparatus according to another embodiment of the present disclosure, the degree of freedom in the arrangement of the first optical lenses 710 and the second optical lenses 720 can be improved.

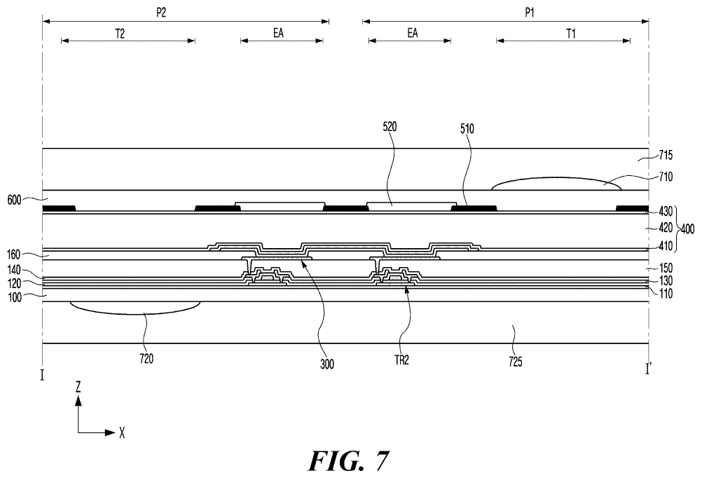

The display apparatus according to the embodiment of the present disclosure is described that each of the second optical lenses 720 has a refractive index different from each first optical lens 710. However, in the display apparatus according to another embodiment of the present disclosure, the second optical lenses 720 can include a same material as the first optical lenses 710. For example, in the display apparatus according to another embodiment of the present disclosure, a lower lens passivation layer 725 can be disposed on the lower surface of the device substrate 100, the surface of each second optical lens 720 having a convex shape can be in direct contact with the lower lens passivation layer 725, and the lower lens passivation layer 725 can have a refractive index smaller than each second optical lens 720, as shown in FIG. 7. The lower lens passivation layer 725 can include an insulating material. For example, the lower lens passivation layer 725 can include an inorganic insulating material. The lower lens passivation layer 725 can include a same material as the upper lens passivation layer 715. Thus, in the display apparatus according to another embodiment of the present disclosure, the degree of freedom in the material of the second optical lenses 720 can be improved.

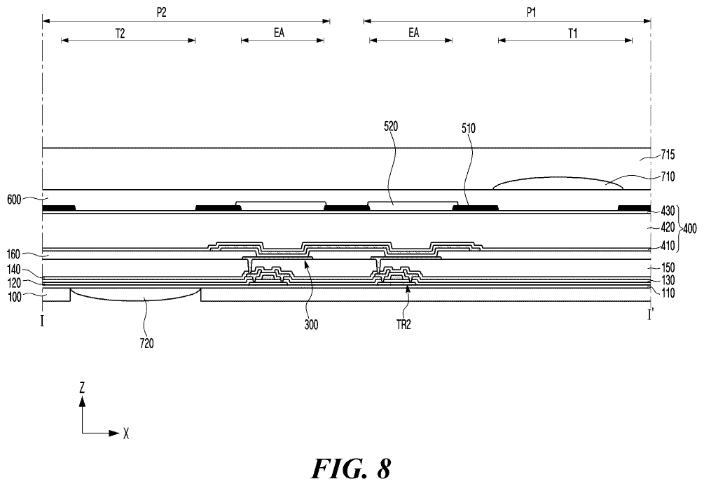

In the display apparatus according to the embodiment of the present disclosure, each of the second optical lenses 720 can include a same material as the device substrate 100. For example, in the display apparatus according to the embodiment of the present disclosure, the second optical lenses 720 can be formed by etching a portion of the device substrate 100, as shown in FIG. 8. A surface of each second optical lens 720 toward the light-emitting devices 300 can be in direct contact with the buffer insulating layer 110. Thus, in the display apparatus according to the embodiment of the present disclosure, a process of forming the second optical lenses 720 can be simplified. And, in the display apparatus according to the embodiment of the present disclosure, the process cost can be reduced.

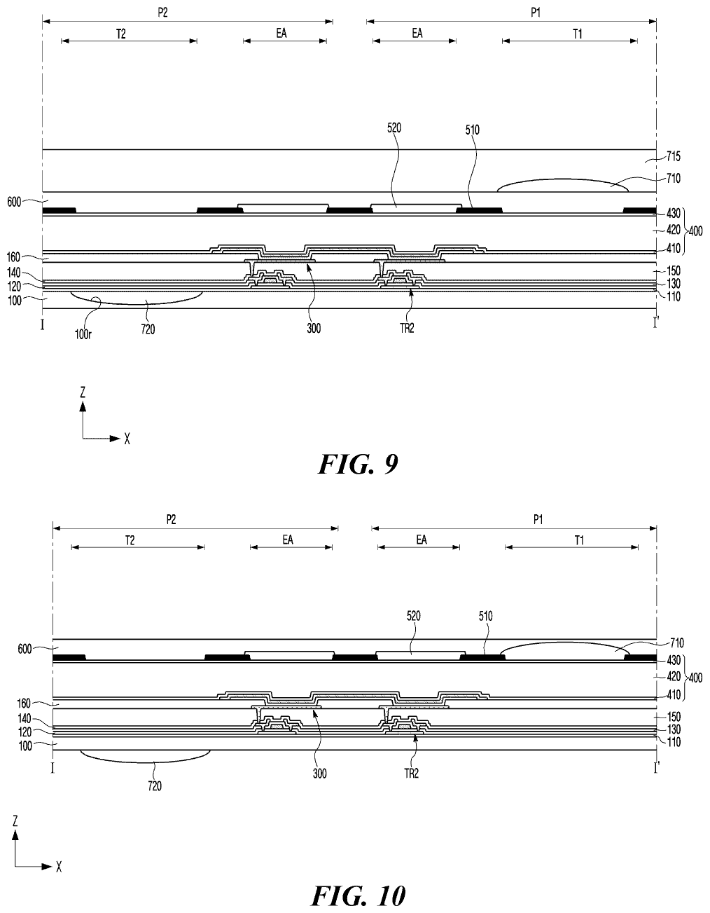

The display apparatus according to the embodiment of the present disclosure is described that the second optical lenses 720 are disposed on the lower surface of the device substrate 100. However, in the display apparatus according to another embodiment of the present disclosure, the second optical lenses 720 can be disposed between the device substrate 100 and the light-emitting devices 300. For example, in the display apparatus according to another embodiment of the present disclosure, a process of forming the second optical lenses 720 can include a process of forming lower recess regions 100r overlapping with the second transmission area T2 of each second pixel area P2 at the upper surface of the device substrate 100, and a process of filling the lower recess regions 100r of the device substrate 100 with a material having a refractive index larger than the device substrate 100, as shown in FIG. 9. Thus, in the display apparatus according to another embodiment of the present disclosure, the amount of the external light passing through the transmission areas T1 and T2 of the device substrate 100 can be increased, without the increase in the overall thickness. Therefore, in the display apparatus according to the embodiment of the present disclosure, the degree of freedom in the location of the second optical lenses 720 can be improved. And, in the display apparatus according to the embodiment of the present disclosure, the degree of freedom in a process of forming the second optical lenses 720 can be improved.

In the display apparatus according to another embodiment of the present disclosure, the lower recess regions 100r of the device substrate 100 can be filled by the buffer insulating layer 110. The buffer insulating layer 110 can include a material having a refractive index larger than the device substrate 100. For example, in the display apparatus according to another embodiment of the present disclosure, a boundary between each second optical lens 720 and the buffer insulating layer 110 cannot be recognized. Thus, in the display apparatus according to another embodiment of the present disclosure, a process of forming the second optical lenses 720 can be simplified. Therefore, in the display apparatus according to another embodiment of the present disclosure, the process efficiency can be improved.

The display apparatus according to the embodiment of the present disclosure is described that the first optical lenses 710 are disposed on a different layer from the color filters 520. However, in the display apparatus according to another embodiment of the present disclosure, the first optical lenses 710 can be formed on various locations. For example, in the display apparatus according to another embodiment of the present disclosure, the first optical lenses 710 can be disposed on a same layer as the color filters 520, as shown in FIG. 10. A surface of each first optical lens 710 toward the light-emitting devices 300 can be in direct contact with the upper surface of the encapsulation structure 400. The surface of each first optical lens 710 having a convex shape can be in direct contact with the filter passivation layer 600, and the filter passivation layer 600 can have a refractive index smaller than each first optical lens 710. Thus, in the display apparatus according to another embodiment of the present disclosure, the overall thickness can be minimized, and the amount of the external light passing through the transmission areas T1 and T2 of the device substrate 100 can be increased. That is, in the display apparatus according to another embodiment of the present disclosure, the degree of freedom in the location of the first optical lenses 710 can be improved.

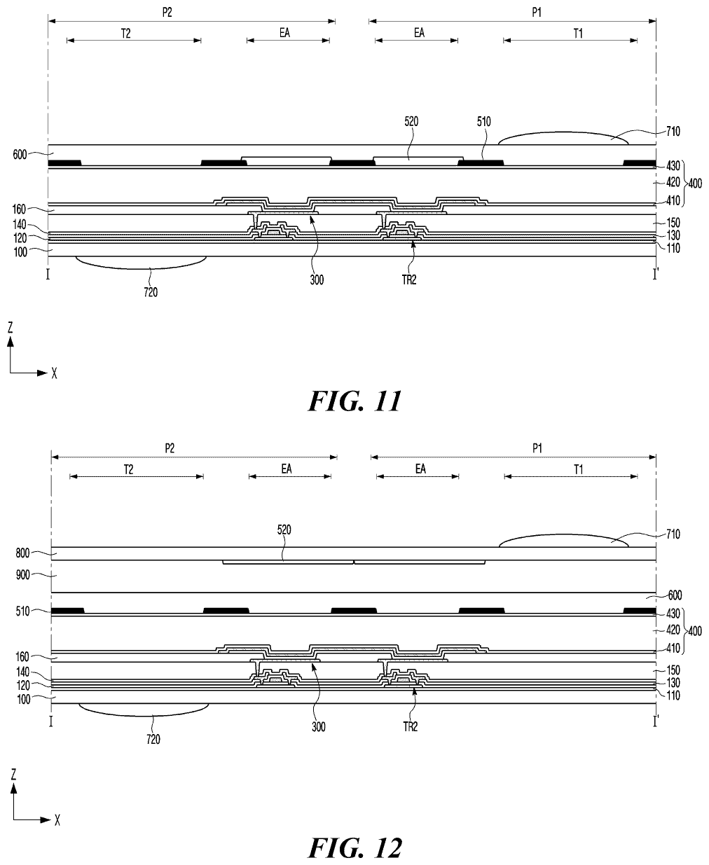

The display apparatus according to the embodiment of the present disclosure is described that the first optical lenses 710 are covered by the upper lens passivation layer 715. However, in the display apparatus according to another embodiment of the present disclosure, the upper lens passivation layer 715 can be omitted. For example, in the display apparatus according to another embodiment of the present disclosure, the surface of each first optical lens 710 having a convex shape can be in direct contact with the air, as shown in FIG. 11. Thus, in the display apparatus according to another embodiment of the present disclosure, the process efficiency can be improved. And, in the display apparatus according to another embodiment of the present disclosure, the process cost can be reduced.

The display apparatus according to the embodiment of the present disclosure is described that the black matrix 510 and the color filters 520 can be disposed side by side on the upper surface of the encapsulation structure 400. However, in the display apparatus according to another embodiment of the present disclosure, the color filters 520 can be disposed on a different layer from the black matrix 510. For example, in the display apparatus according to another embodiment of the present disclosure, an encapsulating substrate 800 can be disposed between the filter passivation layer 600 covering the black matrix 510 and the first optical lenses 710, the color filters 520 can be disposed on a lower surface of the encapsulating substrate 800 toward the filter passivation layer 600, and a filling layer 900 covering the color filters 520 can be in direct contact with the upper surface of the filter passivation layer 600, as shown in FIG. 12. A boundary of the color filters 520 can overlap the black matrix 510. The surface of each first optical lens 710 having a convex shape can be in direct contact with the air. Thus, in the display apparatus according to another embodiment of the present disclosure, the damage of the light-emitting devices 300 due to a process of forming the color filters 520 and a process of forming the first optical lenses 710 can be prevented. Therefore, in the display apparatus according to another embodiment of the present disclosure, the degree of freedom in the material of the color filters 520 and/or the material of the first optical lenses 710 can be improved.

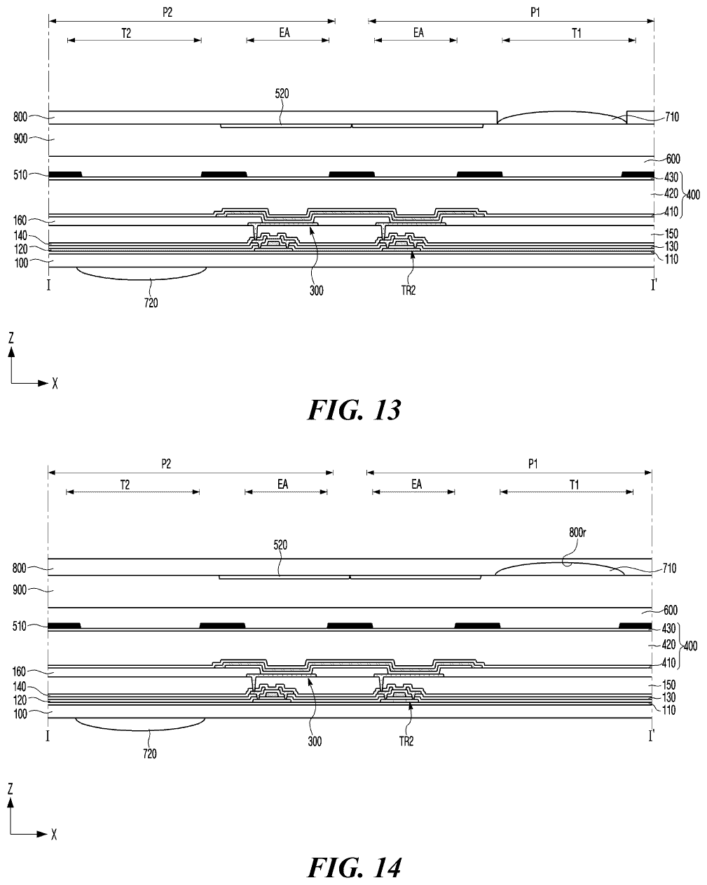

In the display apparatus according to another embodiment of the present disclosure, the first optical lenses 710 can include a same material as the encapsulating substrate 800. For example, in the display apparatus according to another embodiment of the present disclosure, the first optical lenses 710 can be formed by etching a portion of the encapsulating substrate 800, as shown in FIG. 13. A surface of each first optical lens 710 toward the light-emitting devices 300 can be in direct contact with the filling layer 900. Thus, in the display apparatus according to another embodiment of the present disclosure, a process of forming the first optical lenses 710 can be simplified. And, in the display apparatus according to another embodiment of the present disclosure, the process cost can be reduced.

In the display apparatus according to another embodiment of the present disclosure, the first optical lenses 710 can be disposed between the filling layer 900 and the encapsulating substrate 800. For example, in the display apparatus according to another embodiment of the present disclosure, a process of forming the first optical lenses 710 can include a process of forming upper recess regions 800r overlapping with the first transmission area T1 of each first pixel area P1 at a lower surface of the encapsulating substrate 800 toward the device substrate 100, and a process of filling the upper recess regions 800r of the encapsulating substrate 800 with a material having a refractive index larger than the encapsulating substrate 800, as shown in FIG. 14. Thus, in the display apparatus according to another embodiment of the present disclosure, the amount of the external light passing through the transmission areas T1 and T2 can be increased, without the increase in the overall thickness. Therefore, in the display apparatus according to another embodiment of the present disclosure, the degree of freedom in the location of the first optical lenses 710. And, in the display apparatus according to another embodiment of the present disclosure, the degree of freedom in a process of forming the first optical lenses 710 can be improved.

In the display apparatus according to another embodiment of the present disclosure, the upper recess regions 800r of the encapsulating substrate 800 can be filled by the filling layer 900. The filling layer 900 can include a material having a refractive index larger than the encapsulating substrate 800. For example, in the display apparatus according to another embodiment of the present disclosure, a boundary between each first optical lens 710 and the filling layer 900 cannot be recognized. Thus, in the display apparatus according to another embodiment of the present disclosure, a process of forming the first optical lenses 710 can be simplified. Therefore, in the display apparatus according to another embodiment of the present disclosure, the process efficiency can be improved.

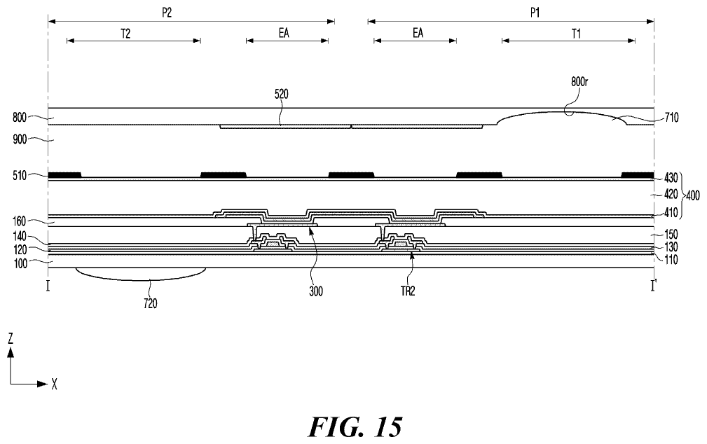

In the display apparatus according to another embodiment of the present disclosure, the filling layer 900 can be formed of a same material as the filter passivation layer 600. A boundary between the filter passivation layer 600 and the filling layer 900 cannot be recognized. For example, in the display apparatus according to another embodiment of the present disclosure, a space between the black matrix 510 and the color filters 520 and the upper recess regions 800r can be completely filled by the filling layer 900, as shown in FIG. 15. Thus, in the display apparatus according to another embodiment of the present disclosure, the process efficiency can be improved. And, in the display apparatus according to the embodiment of the present disclosure, the process cost can be reduced.

In the result, the display apparatus according to the embodiments of the present disclosure can comprise the light-emitting device disposed between the first optical lens and the second optical lens, wherein the first optical lens and the second optical lens can be spaced apart from a path of the light emitted from the light-emitting device, wherein the cross-section of the second optical lens can have a shape symmetrical to the cross-section of the first optical lens with respect to the light-emitting device, and wherein the second optical lens cannot overlap the first optical lens. Thus, in the display apparatus according to the embodiments of the present disclosure, the amount of the external light travelling from the outside of the first optical lens toward the outside of the second optical lens and the amount of the external light traveling from the outside of the second optical lens toward the outside of the first optical lens can be increased, without the decrease in the viewing angle of the real image by the external light. Thereby, in the display apparatus according to the embodiments of the present disclosure, the clarity of the real image recognized by the user can be improved. And, in the display apparatus according to the embodiments of the present disclosure, the low power driving can be possible, and the power consumption can be reduced.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a device substrate including an emission area, a first transmission area, and a second transmission area;
a light-emitting device on a first surface of the device substrate, the light-emitting device overlapping with the emission area;
an encapsulation structure on the first surface of the device substrate, the encapsulation structure covering the light-emitting device;
a first optical lens on the encapsulation structure, the first optical lens overlapping with the first transmission area; and
a second optical lens on a second surface of the device substrate, the second optical lens overlapping with the second transmission area,
wherein a cross-section of the second optical lens has a shape symmetrical to a cross-section of the first optical lens with respect to the device substrate.

2. The display apparatus according to claim 1, wherein the cross-section of the first optical lens has a semicircular shape with respect to the device substrate.

3. The display apparatus according to claim 1, wherein the first optical lens is disposed outside the second transmission area, and the second optical lens is disposed outside the first transmission area.

4. The display apparatus according to claim 3, wherein the device substrate includes a non-emission area between the emission area, the first transmission area, and the second transmission area, and
wherein an edge of the first optical lens and an edge of the second optical lens overlap the non-emission area.

5. The display apparatus according to claim 1, wherein a refractive index of the second optical lens is different from a refractive index of the first optical lens.

6. The display apparatus according to claim 5, further comprising a lens passivation layer on the encapsulation structure,
wherein the lens passivation layer covers the first optical lens,
wherein a refractive index of the lens passivation layer is smaller than the refractive index of the first optical lens.

7. The display apparatus according to claim 1, further comprising a color filter on the encapsulation structure,
wherein the color filter overlaps the emission area, and
wherein the first transmission area and the second transmission area are disposed outside the color filter.

8. The display apparatus according to claim 7, further comprising an encapsulating substrate between the encapsulation structure and the first optical lens,
wherein the color filter is between the encapsulation structure and the encapsulating substrate.

9. A display apparatus comprising:
first optical lenses disposed side by side in a first direction;
second optical lenses disposed side by side in the first direction, the second optical lenses spaced apart from the first optical lenses in a second direction transverse to the first direction; and
light-emitting devices disposed between the first optical lenses and the second optical lenses in the second direction,
wherein each of the first optical lenses and each of the second optical lenses have a cross-section having a convex shape in a direction opposite to the light-emitting devices, and
wherein the second optical lenses are disposed alternately with the first optical lenses.

10. The display apparatus according to claim 9, wherein the light-emitting devices are between the first optical lenses and the second optical lenses in the first direction.

11. The display apparatus according to claim 9, further comprising a device substrate supporting the light-emitting device and the first optical lenses,
wherein the second optical lenses include a same material as the device substrate.

12. The display apparatus according to claim 11, further comprising a buffer insulating layer between the device substrate and the light-emitting devices,
wherein a surface of the device substrate and a surface of each second optical lens toward the light-emitting devices are in contact with the buffer insulating layer.

13. The display apparatus according to claim 11, wherein the first optical lenses include a same material as the second optical lenses.

14. The display apparatus according to claim 13, further comprising an encapsulating substrate on the light-emitting devices,
wherein the encapsulating substrate is on a same layer as the first optical lenses.

15. The display apparatus according to claim 9, wherein the surface of each second optical lens having a convex shape has a same curvature as the surface of each first optical lens having a convex shape.

16. The display apparatus according to claim 1, wherein the first optical lens and the second optical lens are configured to refract external light incident from outside the display apparatus to travel in a direction substantially perpendicular to the device substrate.

17. The display apparatus according to claim 1, wherein the first optical lens and the second optical lens do not overlap each other in a thickness direction of the device substrate.

18. The display apparatus according to claim 1, wherein the first transmission area and the second transmission area are not overlapped by a black matrix or a color filter.

19. The display apparatus according to claim 6, wherein a difference between the refractive index of the lens passivation layer and the first optical lens is selected to cause external light to travel substantially parallel after refraction.

20. The display apparatus according to claim 1, wherein the second optical lens is disposed within or below an upper surface of the device substrate, between the device substrate and the light-emitting device.

21. The display apparatus according to claim 1, wherein each of the first optical lens and the second optical lens has a size larger than the corresponding transmission area.
